(19) United States
(12) Patent Application Publication
(10) Pub. No.: US 2023/0374695 A1
(43) Pub. Date: Nov. 23, 2023

(54) SYNTHESIS OF H-BN USING METALLIC SOLVENT AND HIGH-TEMPERATURE SOAKS

(71) Applicant: NS Nanotech, Inc., Ann Arbor, MI (US)

(72) Inventors: Evrard LACROIX, Brighton, MI (US); Seth COE-SULLIVAN, Rolling HIlls Estates, CA (US); Matthew STEVENSON, Ann Arbor, MI (US); David LALEYAN, Quebec (CA)

(21) Appl. No.: 18/199,285

(22) Filed: May 18, 2023

Related U.S. Application Data
(60) Provisional application No. 63/343,509, filed on May 18, 2022.

(51) Int. Cl. C30B 9/06; C30B 9/10; C30B 29/40

(52) U.S. Cl. CPC C30B 9/06; C30B 9/10; C30B 29/403

(57) ABSTRACT

To produce hexagonal boron nitride (h-BN), boron and nitrogen are added to a metallic solvent in a crucible in a reaction chamber and heat-treated. In an absorption step, a first soak is performed at a first temperature that is high enough to cause absorption of the nitrogen and boron into the metallic solvent. In a nucleation step after the absorption step, the first temperature is rapidly reduced to a second temperature, and h-BN nuclei are formed in the metallic solvent. In a growth step after the nucleation step, a second soak is performed at the second temperature to grow the h-BN nuclei. After the growth step, the h-BN nuclei are separated from the metallic solvent.

### RELATED U.S. APPLICATION

This application claims priority to the U.S. Provisional Application entitled “Synthesis of H-BN Using Metal Solvent and High-Temperature Soaks,” by E. Lacroix et al., Ser. No. 63/343,509, filed May 18, 2022, hereby incorporated by reference in its entirety.

### BACKGROUND

The use of metal solvents has been proven successful in the past to generate high purity hexagonal boron nitride (h-BN) that shows far-UV (ultra-violet) light emission. Conventional processes include heating a binary alloy containing nickel (Ni) and one of chromium (Cr), iron (Fe), or molybdenum (Mo) (each of which may be referred to herein as “the alloy”) in a medium containing boron (B) and nitrogen (N). The addition of B and N to the environment has been achieved by: having high purity elemental boron in contact with the alloy in a crucible in a N2 atmosphere; having cosmetic-grade h-BN powder in contact with the alloy in a crucible in a N2 atmosphere; and setting the alloy in a BN crucible in a N2 atmosphere.

The reaction has generally been performed by soaking one of the above combinations at high temperature (for example, 1350 degrees Celsius [° C.], 1400° C., 1500° C., or 1600° C.) for a few hours (for example, six or 12 hours). The furnace is then cooled down slowly to promote growth at a slow rate of 4° C. per hour to 1200° C., where a more rapid ramp rate is implemented to finish cooling down to room temperature (typically 5° C. per minute). However, the synthesis methods described above are low yielding and have very inconsistent emission spectra.

### SUMMARY

Embodiments according to the present disclosure include processes for producing h-BN and products (articles of manufacture) of these processes.

In embodiments of the disclosed processes, boron and nitrogen are added to a metallic solvent in a crucible in a reaction chamber and heat-treated. The process includes an absorption step, during which a first soak is performed at a first temperature that is high enough to cause absorption of the nitrogen and boron into the metallic solvent. The process also includes a nucleation step after the absorption step, during which the first temperature is rapidly reduced to a second temperature and h-BN nuclei are formed in the metallic solvent. The process also includes a growth step after the nucleation step, during which a second soak is performed at the second temperature to grow the h-BN nuclei. After the growth step, the h-BN nuclei are separated from the metallic solvent.

The absorption, nucleation, and growth steps yield significantly more material, due to the combination of a B- and N-saturated metallic solvent and the presence of h-BN nuclei caused by the absorption step and the nucleation step, respectively. The disclosed processes yield consistent material quantities and qualities, having a consistent emission spectra with maximum peak ratios between the far-UV wavelengths and the defect emission wavelengths that are greater than three, and exhibiting a narrow band emission at a wavelength lower than 240 nanometers (nm).

These and other objects and advantages of the various embodiments of the present invention will be recognized by those of ordinary skill in the art after reading the following detailed description of the embodiments that are illustrated in the various drawing figures.

### BRIEF DESCRIPTION OF DRAWINGS

The accompanying drawings, which are incorporated in and form a part of this specification and in which like numerals depict like elements, illustrate embodiments of the present disclosure and, together with the detailed description, serve to explain the principles of the disclosure. The drawings are not necessarily to scale.

FIG. 1 is a flowchart of a process for producing h-BN in embodiments according to the present disclosure.

FIG. 2 is a plot of temperature versus time for an example of the heat treatment just described in embodiments according to the present disclosure.

FIG. 3 is a plot of light intensity versus wavelength for light emitted by h-BN produced using a process in embodiments according to the present disclosure.

FIG. 4 illustrates an example of an apparatus that can be used for performing a process of producing h-BN in embodiments according to the present disclosure.

FIG. 5 illustrates an example of an article of manufacture produced using a process in embodiments according to the present disclosure.

### DETAILED DESCRIPTION

Reference will now be made in detail to the various embodiments of the present disclosure, examples of which are illustrated in the accompanying drawings. While described in conjunction with those embodiments, it will be understood that they are not intended to limit the disclosure to those embodiments. On the contrary, the disclosure is intended to cover alternatives, modifications and equivalents, which may be included within the spirit and scope of the disclosure as defined by the appended claims. Furthermore, in the following detailed description, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The figures are not necessarily drawn to scale, and only portions of the devices and structures depicted, as well as the various layers that form those structures, are or may be shown. For simplicity of discussion and illustration, only one or two devices or structures may be described, although in actuality more than one or two devices or structures may be present or formed. Also, while certain elements, components, and layers are discussed, embodiments according to the invention are not limited to those elements, components, and layers. For example, there may be other elements, components, layers, and the like in addition to those discussed.

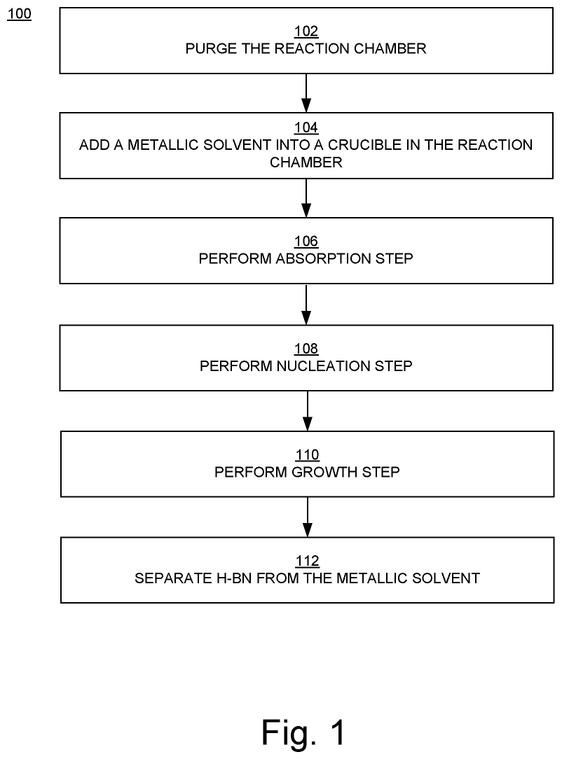

FIG. 1 is a flowchart 100 of a process for producing h-BN in embodiments according to the present disclosure. Other processes and steps may be performed along with the processes and steps discussed herein; that is, there may or may not be processes and steps performed before, in between and/or after the steps shown in FIG. 1 and described herein. Importantly, if there are such other processes and steps, embodiments according to the present disclosure can be integrated with them. Generally speaking, embodiments according to the present disclosure can, for example, replace all or portions of a conventional process.

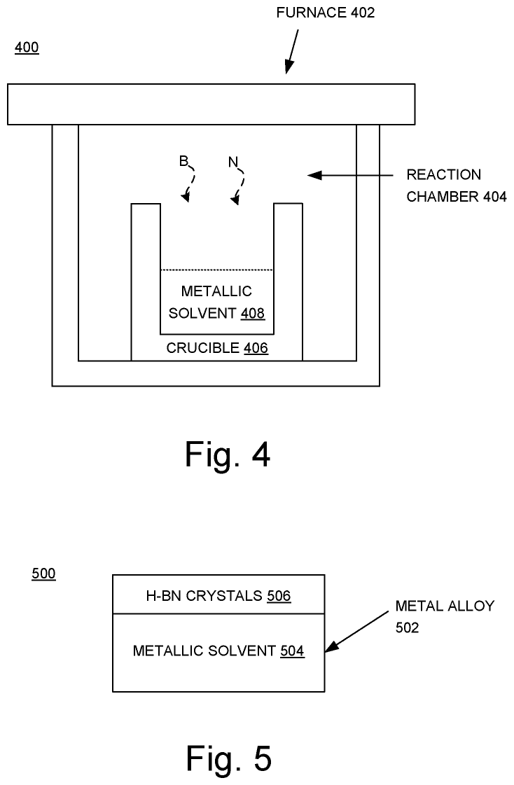

The process described below takes place in a high-temperature furnace, under enough nitrogen flow and/or pressure to prevent air contamination in the reaction chamber of the furnace. An example of a furnace, showing some of its basic components, is illustrated in FIG. 4.

In overview, the disclosed process includes a heat treatment that includes two different soak temperatures and a cooling ramp from the first soak temperature to the second soak temperature. The first soak temperature is the highest temperature and is significant enough to promote nitrogen and boron absorption into a metallic solvent. This first soak, referred to herein as the absorption step, is performed for a long enough period of time to saturate the metallic solvent with boron and nitrogen. The second soak, referred to herein as the growth step, is at a temperature lower than that of the absorption step and the boron nitride dissociation temperature to favor crystal growth. The temperature difference between the first temperature (absorption step) and the second temperature (growth step) is high enough that the boron and nitrogen in the metallic solvent become supersaturated and create h-BN nuclei during the nucleation step, which is performed between the absorption step and the growth step when the temperature is reduced from the first temperature to the second temperature. The cooling rate during the nucleation step is high enough to ensure that enough h-BN nuclei are present for adequate growth to occur during the growth step.

The heating rate before the absorption step and the cooling rate after the growth step are each fast enough to limit their impact on the overall process, but not so fast that they cause thermal shock. In embodiments, the heating rate before the absorption step and the cooling rate after the growth step are each lower than or equal to 5° C. per minute (° C./min) (for example, 5° C./min, 4° C./min, 3° C./min, 2° C./min, or 1° C./min); however, the present invention is not limited to these specific values or the range of these values.

In block 102 of FIG. 1, in an embodiment, the reaction chamber of a high-temperature furnace is purged to remove any oxygen, carbon, moisture, or other air contamination.

In block 104, a metallic solvent is added into a crucible in the reaction chamber. In embodiments, the metallic solvent consists of or includes, for example: Ni, Cr, Mo, Fe, zirconium (Zr), titanium (Ti), or hafnium (Hf); however, the present invention is not so limited. In embodiments, the metallic solvent includes at least two of those elements, in any combination. In other embodiments, the metallic solvent includes at least three of those elements, in any combination. In an embodiment, the metallic solvent also includes boron. In embodiments, the crucible is made of, for example: aluminum oxide (Al₂O₃), BN, Mo, tungsten (W), or zirconium dioxide (ZrO₂); however, the present invention is not so limited.

Although a single crucible is mentioned in this example, there can be more than one crucible in the reaction chamber, and the disclosed process can be performed using all or some of the one or more crucibles that may be in the reaction chamber.

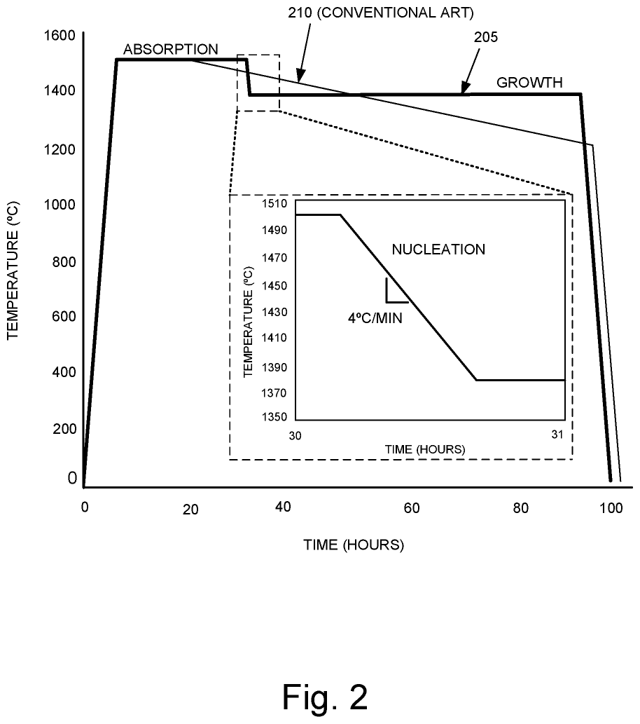

In block 106 (the aforementioned absorption step), boron and nitrogen are added to the metallic solvent. More specifically, a first soak is performed at a first temperature that is high enough to cause nitrogen and boron absorption into the metallic solvent. During the first soak, the first temperature is substantially constant or flat (see FIG. 2). “Substantially constant or flat,” as used herein, means that there may be some variation in the first temperature, but the variation is small enough to be insignificant in terms of the overall effect on the nitrogen and boron absorption. In embodiments, the first temperature is greater than or equal to 1350° C. (for example, 1350° C., 1400° C., 1450° C., 1500° C., 1550° C., or 1600° C.); however, the present invention is not limited to these specific values or the range of these values. In embodiments, the first soak is performed for six hours or more (for example, 6, 12, 24, 48, or 60 hours); however, the present invention is not limited to these specific values or the range of these values.

In block 108 of FIG. 1 (the aforementioned nucleation step), h-BN nuclei are formed in the metallic solvent. The nucleation step implements a cooling ramp between the absorption step and the growth step to reduce the first soak temperature to a second temperature at which the second soak will be performed. In embodiments, the cooling rate is greater than or equal to 1° C./min (for example, 1° C./min, 2° C./min, 3° C./min, 4° C./min, or 5° C./min); however, the present invention is not limited to these specific values or the range of these values.

In block 110 (the aforementioned growth step), the second soak is performed at the second temperature to grow the h-BN nuclei. During the second soak, the second temperature is substantially constant or flat (see FIG. 2). “Substantially constant or flat,” as used herein, means that there may be some variation in the second temperature, but the variation is small enough to be insignificant in terms of the overall effect on the growth of the h-BN nuclei. The temperature difference between the first temperature (absorption step) and the second temperature (growth step) is high enough that the boron and nitrogen in the metallic solvent become supersaturated and form the h-BN nuclei during the nucleation step. The second temperature therefore is lower than that of the absorption step and the boron nitride dissociation temperature. In embodiments, the temperature difference between the first and second temperatures is about 50° C. or more; however, the present invention is not limited to these specific values or the range of these values. In embodiments, the second soak is performed for 24 hours or more (for example, 24, 30, 40, 50, 60, or 70 hours); however, the present invention is not limited to these specific values or the range of these values.

As a result of the growth step, a solid metal alloy that includes the metallic solvent and solidified h-BN crystals on a surface of the solid metal alloy is formed (see FIG. 5). In embodiments, the metallic solvent includes at least two of the following elements: Ni, Cr, Mo, Fe, Zr, Ti, and Hf. In other embodiments, the metallic solvent includes at least three of the following elements: Ni, Cr, Mo, Fe, Zr, Ti, and Hf. In an embodiment, the metallic solvent also includes boron in addition to the other at least two or at least three elements listed just above.

In block 112 of FIG. 1, the h-BN nuclei are separated from the metallic solvent (e.g., from the metal alloy that includes the metallic solvent). In an embodiment, h-BN crystals are separated from the metallic solvent using ball milling that uses a polytetrafluoroethylene (PTFE) milling medium. Other separation techniques include, but are not limited to, chemical exfoliation or thermal shock.

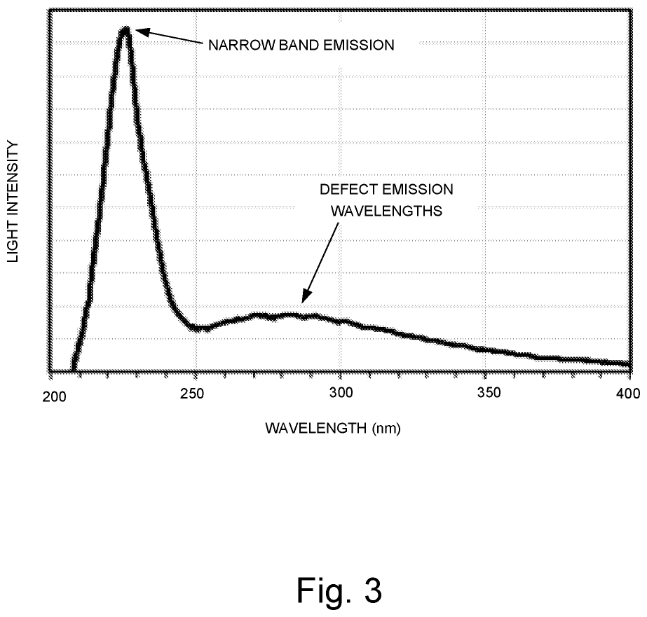

The process described above yields consistent material quantities and qualities, with maximum peak ratios between the far-UV wavelengths and defect emission wavelengths that are greater than three, having a consistent emission spectra, and exhibiting a narrow band emission at a wavelength lower than 240 nm (see FIG. 3). The absorption, nucleation, and growth steps yield significantly more material, due to the combination of a B- and N-saturated metallic solvent and the presence of h-BN nuclei caused by the absorption step and the nucleation step, respectively.

The disclosed process is highly reproducible and is therefore scalable to an industrial level, which would yield significant quantities of high purity h-BN at an affordable price. For instance, the disclosed process can be used to grow high quantities of optical quality h-BN for optical applications. For example, 20 milligrams (mg) of material can be produced in a single crucible, or as much as 50 mg or as much as 150 mg of material can be produced in a single crucible. In addition, multiple (such as but not limited to four crucibles) can be used in a single process run simultaneously, or 10 crucibles or 24 crucibles can be used in a single run. As such, the disclosed process can yield, for example: hundreds of milligrams in a single batch or grams of material in a single batch, and potentially tens of grams in a single batch of material can be produced.

Furthermore, the h-BN can be milled into a powder or large flakes that can be harvested to generate high-purity h-BN targets to sputter thin, high-purity h-BN films. Such products can be used to create far-UV emitting devices that can be used to create far-UV light emitting devices (for example, for disinfection purposes).

FIG. 2 is a temperature profile 205 showing temperature versus time for an example heat treatment in embodiments according to the present disclosure. The figure also includes a temperature profile 210 showing temperature versus time for a conventional process.

An initial heating rate raises the temperature in the reaction chamber to the aforementioned first temperature. In the example of FIG. 2, the first temperature is about 1500° C. In this example, the heating rate is less than or equal to about 5° C./min. For the duration of the absorption step (block 106 of FIG. 1), the temperature remains substantially constant at the first temperature. In the example of FIG. 2, the duration of the absorption step is about 24 hours.

The nucleation step (block 108 of FIG. 1) follows the absorption step. During the nucleation step, the temperature in the reaction chamber is reduced to the aforementioned second temperature. In this example, the second temperature is about 1380° C.

The temperature profile of the nucleation step is shown in the inset in FIG. 2. In this example, the first temperature is reduced to the second temperature at a relatively high rate of 4° C./min over a period of less than one hour (in this example, in less than about 30 minutes). As illustrated in the figure, the cooling rate in the disclosed process is significantly faster than the cooling rate in the conventional art.

The growth step (block 110 of FIG. 1) follows the nucleation step. For the duration of the growth step, the temperature remains substantially constant at the second temperature. In the example of FIG. 2, the duration of the growth step is about 70 hours.

After the growth step, the reaction chamber is cooled at a prescribed cooling rate to room temperature. In this example, the cooling rate is less than or equal to about 5° C./min.

Thus, h-BN is grown using a multi-step (e.g., three-step) heat treatment process that is significantly different than the conventional art process. In the conventional art process, a slow cooldown is performed after the one and only soak; in contrast, a rapid cooldown (the nucleation step) from the first temperature to the second temperature is performed in embodiments according to the present disclosure. The relatively rapid transition from the first temperature to the second temperature in the disclosed process creates a condition in which the hot metallic solvent is supersaturated, and so a greater amount of h-BN is precipitated relative to the conventional art. Also in contrast to the conventional art, embodiments according to the present disclosure include two soaks (the absorption step and the growth step) during which the soak temperatures are held substantially constant, while in the conventional art only a single soak is performed. Furthermore, in embodiments according to the present disclosure, the duration of the first soak may be longer than the single soak performed in the conventional art.

FIG. 3 is a plot of light intensity versus wavelength for light emitted by h-BN produced using a process (FIG. 1) in embodiments according to the present disclosure. The intensity of light may be measured in terms of counts or milliwatts (mW), for example. The h-BN produced by the process disclosed herein exhibits a narrow band emission at a wavelength lower than 240 nm, and has an emission spectrum in which the peak ratios between the far-UV wavelengths (wavelengths less than 240 nm) and the defect emission wavelengths are greater than three. In the example of FIG. 3, a ratio of about five is illustrated; however, ratios other than those illustrated (including ratios greater than five) are potentially possible.

FIG. 4 illustrates an example of an apparatus 400 that can be used for performing a process of producing h-BN (the process of FIG. 1) in embodiments according to the present disclosure. Only selected components of such an apparatus are illustrated. In the example of FIG. 4, the apparatus 400 includes a furnace 402 with a controlled atmosphere, and one or more crucibles (e.g., the crucible 406) to hold the metallic solvent 408 in place in the reaction chamber 404.

To mitigate contamination of the h-BN in the reaction chamber 404 (for example, contamination from crucible material or from the metallic solvent), the apparatus 400 is built as a high-purity system. For example, enough nitrogen flow and/or pressure can be provided to prevent air contamination in the reaction chamber 404. Also, the process temperatures (e.g., those described above) can be chosen to limit evaporation or diffusion of certain elements.

FIG. 5 is a block diagram illustrating an example of an article of manufacture 500 produced in embodiments according to the present disclosure (e.g., in block 110 of FIG. 1). The article of manufacture 500 includes a solid metal alloy 502 that includes a metallic solvent 504 (e.g., the metallic solvent 408 of FIG. 4, or derived from the metallic solvent 408) and solidified h-BN crystals 506 on a surface of the solid metal alloy. In embodiments, the metallic solvent 504 includes at least two of the following elements: Ni, Cr, Mo, Fe, Zr, Ti, and Hf. In other embodiments, the metallic solvent 504 includes at least three of the following elements: Ni, Cr, Mo, Fe, Zr, Ti, and Hf. In an embodiment, the metallic solvent 504 also includes boron in addition to the other at least two or at least three elements listed just above.

Although the subject matter has been described in language specific to structural features and/or methodological acts, it is to be understood that the subject matter defined in the present disclosure is not necessarily limited to the specific features or acts described above. Rather, the specific features and acts described above are disclosed as example forms of implementing the present disclosure.

Embodiments according to the invention are thus described. While the present invention has been described in particular embodiments, the invention should not be construed as limited by such embodiments, but rather construed according to the following claims.

What is claimed is:

1. A process for producing hexagonal boron nitride (h-BN), the process comprising:
an absorption step comprising performing a first soak at a first temperature that is high enough to cause nitrogen and boron absorption into a metallic solvent;
a nucleation step after the absorption step and comprising forming h-BN nuclei in the metallic solvent;
a growth step after the nucleation step and comprising performing a second soak at a second temperature less than the first temperature to grow the h-BN nuclei; and
after the growth step, separating the h-BN nuclei from the metallic solvent.

2. The process of claim 1, wherein the nucleation step comprises a cooling ramp from the first temperature to the second temperature with a cooling rate greater than 0.1° C. per minute.

3. The process of claim 1, wherein the nucleation step comprises a cooling ramp from the first temperature to the second temperature with a cooling rate greater than 1° C. per minute.

4. The process of claim 1, wherein the nucleation step comprises a cooling ramp from the first temperature to the second temperature with a cooling rate greater than 4° C. per minute.

5. The process of claim 1, wherein the nucleation step comprises a cooling ramp from the first temperature to the second temperature with a cooling rate greater than 5° C. per minute.

6. The process of claim 1, wherein a temperature difference between the first temperature and the second temperature is large enough that at least one of the boron and the nitrogen become supersaturated in the metallic solvent and create h-BN nuclei during the nucleation step.

7. The process of claim 6, wherein the temperature difference is greater than or equal to 50° C.

8. The process of claim 1, performed in a reaction chamber, wherein the process further comprises purging the reaction chamber to remove contamination from the reaction chamber prior to the heat treatment.

9. The process of claim 1, performed in a reaction chamber, wherein the process further comprises preventing contamination in the reaction chamber, wherein said preventing comprises an operation selected from the group consisting of: controlling nitrogen flow in the reaction chamber; and controlling pressure in the reaction chamber.

10. The process of claim 1, wherein the metallic solvent is selected from the group of elements consisting of: Ni, Cr, Mo, Fe, Zr, Ti, and Hf, in any combination of two or more of the elements in the group.

11. The process of claim 1, wherein the metallic solvent is in a crucible, and wherein the crucible comprises material selected from the group consisting of: Al₂O₃, BN, Mo, W, and ZrO₂.

12. The process of claim 1, wherein the first temperature is substantially constant and greater than or equal to 1350° C.

13. The process of claim 1, wherein the first soak is performed for a period of time greater than or equal to six hours.

14. The process of claim 1, wherein the second soak is performed for a period of time greater than or equal to 12 hours.

15. The process of claim 1, further comprising a heating rate before the absorption step and a cooling rate after the growth step that are each less than or equal to 5° C. per minute.

16. The process of claim 1, wherein, after the growth step, the metallic solvent cools to produce a solid metal alloy comprising the metallic solvent and also comprising crystals comprising the h-BN nuclei on a surface of the solid metal alloy.

17. A product comprising h-BN produced by the process of claim 1.

18. The product of claim 17, wherein the h-BN has a maximum peak ratio between far-UV wavelengths and a defect emission wavelength greater than three, and wherein the h-BN exhibits a narrow band emission at a wavelength lower than 240 nanometers.

19. An article of manufacture comprising hexagonal boron nitride (h-BN), wherein the h-BN is manufactured by a process comprising:
an absorption step comprising performing a first soak at a first temperature that is high enough to cause nitrogen and boron absorption into a metallic solvent;
a nucleation step after the absorption step and comprising forming h-BN nuclei in the metallic solvent, wherein the nucleation step comprises a cooling ramp from the first temperature to the second temperature, wherein as a result of the absorption step and the nucleation step the crucible contains a combination of the h-BN nuclei and the metallic solvent, and wherein the metallic solvent is at least one of boron-saturated and nitrogen-saturated; and
a growth step after the nucleation step and comprising performing a second soak at a second temperature to grow the h-BN nuclei;
wherein, after the growth step, the h-BN nuclei and the metallic solvent cool to produce a solid metal alloy comprising the metallic solvent and also comprising h-BN crystals formed from the h-BN nuclei on a surface of the solid metal alloy.

20. The article of manufacture of claim 19, wherein the process further comprises separating the h-BN crystals from the solid metal alloy to produce h-BN.

21. The article of manufacture of claim 20, wherein the h-BN has a maximum peak ratio between far-UV wavelengths and a defect emission wavelength greater than three, and wherein the h-BN exhibits a narrow band emission at a wavelength lower than 240 nanometers.

22. The article of manufacture of claim 19, wherein a temperature difference between the first temperature and the second temperature is large enough that at least one of the boron and the nitrogen become supersaturated in the metallic solvent and create the h-BN nuclei during the nucleation step.

23. The article of manufacture of claim 22, wherein the temperature difference is greater than or equal to 50° C.

24. The article of manufacture of claim 19, wherein the cooling ramp has a cooling rate that is greater than 0.1° C. per minute, greater than 1° C. per minute, greater than 4° C. per minute, or greater than 5° C. per minute.

25. The article of manufacture of claim 19, wherein the metallic solvent is selected from the group of elements consisting of: Ni, Cr, Mo, Fe, Zr, Ti, and Hf, in any combination of two or more of the elements in the group.

26. The article of manufacture of claim 19, wherein the first temperature is substantially constant and greater than or equal to 1350° C.

27. The article of manufacture of claim 19, wherein the first soak is performed for a period of time greater than or equal to six hours, and wherein the second soak is performed for a period of time greater than or equal to 12 hours.

28. The article of manufacture of claim 19, wherein the h-BN nuclei and the B-saturated and N-saturated metallic solvent cool at a cooling rate that is less than or equal to 5° C. per minute.

29. An article of manufacture, comprising:
a solid metal alloy comprising a metallic solvent, wherein the metallic solvent comprises at least two elements of a group consisting of: Ni, Cr, Mo, Fe, Zr, Ti, and Hf; and
solidified hexagonal boron nitride (h-BN) crystals on a surface of the solid metal alloy.

30. The article of manufacture of claim 29, wherein the metallic solvent comprises at least three elements of the group.

31. The article of manufacture of claim 29, wherein the metallic solvent further comprises boron.
